(19) United States
(12) Patent Application Publication
(10) Pub. No.: US 2025/0357444 A1
(43) Pub. Date: Nov. 20, 2025

(54) MULTI-INTERPOSER STRUCTURES AND METHODS OF MAKING THE SAME

(71) Applicant: Taiwan Semiconductor Manufacturing Company Limited, Hsinchu (TW)

(72) Inventors: Hsien-Wei CHEN, Hsinchu CIty (TW); Shin-Puu JENG, Po-Shan Village (TW)

(21) Appl. No.: 19/284,858

(22) Filed: Jul. 30, 2025

Related U.S. Application Data
(62) Division of application No. 17/735,536, filed on May 3, 2022.
(60) Provisional application No. 63/214,066, filed on Jun. 23, 2021.

(51) Int. Cl. H01L 25/10; H01L 23/00; H01L 23/14; H01L 23/498; H01L 23/538; H01L 23/64; H01L 25/00; H01L 25/065

(52) U.S. Cl. CPC H01L 25/105; H01L 23/145; H01L 23/49816; H01L 23/49833; H01L 23/5385; H01L 23/5386; H01L 23/642; H01L 25/0655; H01L 25/50; H01L 24/16; H01L 24/32; H01L 24/73; H01L 2224/16225; H01L 2224/32225; H01L 2224/73204; H01L 2924/1425; H01L 2924/1434; H01L 2924/30101; H01L 2924/30105; H01L 2924/3011

(57) ABSTRACT

Various disclosed embodiments include a substrate, a first interposer coupled to the substrate and to a first semiconductor device die, and a second interposer coupled to the substrate and to a second semiconductor device die. The first semiconductor device die may be a serializer/de-serializer die and the first semiconductor device die coupled to the first interposer may be located proximate to a sidewall of the substrate. In certain embodiments, the second semiconductor device die may be a system-on-chip die. In further embodiments, the second interposer may also be coupled to high bandwidth memory die. Placing a serializer/de-serializer die proximate to a sidewall of a substrate allows a length of electrical pathways to be reduced, thus reducing impedance and RC delay. The use of smaller, separate, interposers also reduces complexity of fabrication of interposers and similarly lowers impedance associated with redistribution interconnect structures associated with the interposers.

### RELATED APPLICATION

This application is a divisional of U.S. patent application Ser. No. 17/735,536 entitled “Multi-Interposer Structures And Methods Of Making The Same” filed May 3, 2022, which claims priority to U.S. Provisional Patent Application No. 63/214,066 entitled “Multi-interposer Modulus (MiM) structures for high speed solution” filed on Jun. 23, 2021, the entire contents of both of which are hereby incorporated by reference for all purposes.

### BACKGROUND

The semiconductor industry has grown due to continuous improvements in integration density of various electronic components (e.g., transistors, diodes, resistors, capacitors, etc.). For the most part, these improvements in integration density have come from successive reductions in minimum feature size, which allow more components to be integrated into a given area.

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (POP), System on Chip (SoC), or System on Integrated Circuit (SoIC) devices. Some of these three-dimensional devices (e.g., 3DIC, SoC, SoIC) are prepared by placing chips over chips on a semiconductor wafer level. These three-dimensional devices provide improved integration density and other advantages, such as faster speeds and higher bandwidth, because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of an exemplary semiconductor device.

FIG. 1B is a vertical cross-sectional view of a further exemplary semiconductor device structure.

FIG. 1C is a vertical cross-sectional view of a further exemplary semiconductor device structure, according to various embodiments.

FIG. 1D is a vertical cross-sectional view of an exemplary semiconductor device structure having two semiconductor device dies coupled to a single interposer, according to various embodiments.

FIG. 1E is a plan view of the exemplary semiconductor device structure of FIG. 1D, according to various embodiments.

FIG. 1F is a vertical cross-sectional view of an exemplary semiconductor device structure having two semiconductor device dies on two respective interposers, according to various embodiments.

FIG. 1G is a top view of the exemplary semiconductor device structure of FIG. 1F, according to various embodiments.

FIG. 2 is a vertical cross-sectional view of an intermediate structure used in the formation of a plurality of chiplets, according to various embodiments.

FIG. 3 is a vertical cross-sectional view of a further intermediate structure used in the formation of a plurality of chiplets, according to various embodiments.

FIG. 4 is a vertical cross-sectional view of a further intermediate structure used in the formation of a plurality of chiplets, according to various embodiments.

FIG. 5 is a vertical cross-sectional view of a further intermediate structure used in the formation of a plurality of chiplets, according to various embodiments.

FIG. 6 is a vertical cross-sectional view of an intermediate structure used in the formation of a plurality of chiplets, according to various embodiments.

FIG. 7 is a vertical cross-sectional view of a further intermediate structure used in the formation of a plurality of chiplets, according to various embodiments.

FIG. 8 is a vertical cross-sectional view of a further intermediate structure used in the formation of a plurality of chiplets, according to various embodiments.

FIG. 9 is a vertical cross-sectional view of a further intermediate structure used in the formation of a plurality of chiplets, according to various embodiments.

FIG. 10 is a vertical cross-sectional view of a system having a first chiplet and a second chiplet attached to a package substrate, according to various embodiments.

FIG. 11 is a vertical cross-sectional view of a further system having a first chiplet and a second chiplet attached to a package substrate, according to various embodiments.

FIG. 12 is a vertical cross-sectional view of a further system having a first chiplet and a second chiplet attached to a package substrate, according to various embodiments.

FIG. 13 is a flowchart illustrating various operations of a method of fabricating a semiconductor device, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

One package integration strategy includes formation of a Chip on Wafer on Substrate (CoWoS) structure that includes a SoC die integrated with a high bandwidth memory (HBM) die. The CoWoS structure may also include a serializer/de-serializer device die that is configured to communicate with other CoWoS structures or with other system components. To minimize ohmic losses and RC delay, the SoC die and the HBM die may be disposed on and coupled to an interposer. Some embodiments may also include the serializer/de-serializer device die disposed on and coupled to the same interposer as the SoC die and HBM die. To minimize ohmic loss and RC delay associated with the serializer/de-serializer device die, however, it may be desirable to place the serializer/de-serializer device die proximate to a sidewall of a package substrate on which the CoWoS structure is formed to reduce the length of electrical pathways connecting the serializer/de-serializer device die to neighboring devices. Such placement, however, may necessitate a larger interposer, which may lead to increased complexity and ohmic loss associated redistribution interconnect structures within the interposer.

Disclosed embodiments solve the above problems by using two separate interposers, one for the SoC die and the HBM die, and one for the serializer/de-serializer device die. Each interposer is smaller and less complex than a corresponding single interposer configured to house the SoC die, the HBM die, and the serializer/de-serializer device die. As such, ohmic loss and RC delay associated with the interposers may be reduced. Further, the use of two interposers allows the serializer/de-serializer device die to be placed proximate to a sidewall of the package substrate, thus reducing the length of electrical pathways connecting the serializer/de-serializer device die to neighboring devices, thereby reducing ohmic loss and RC delay associated with the serializer/de-serializer device die.

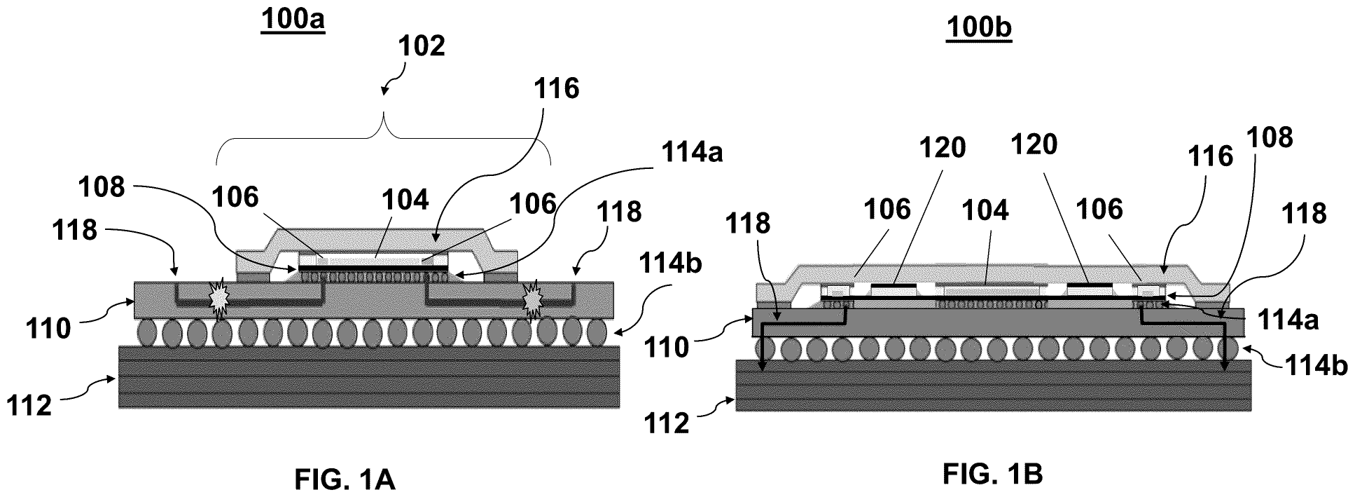

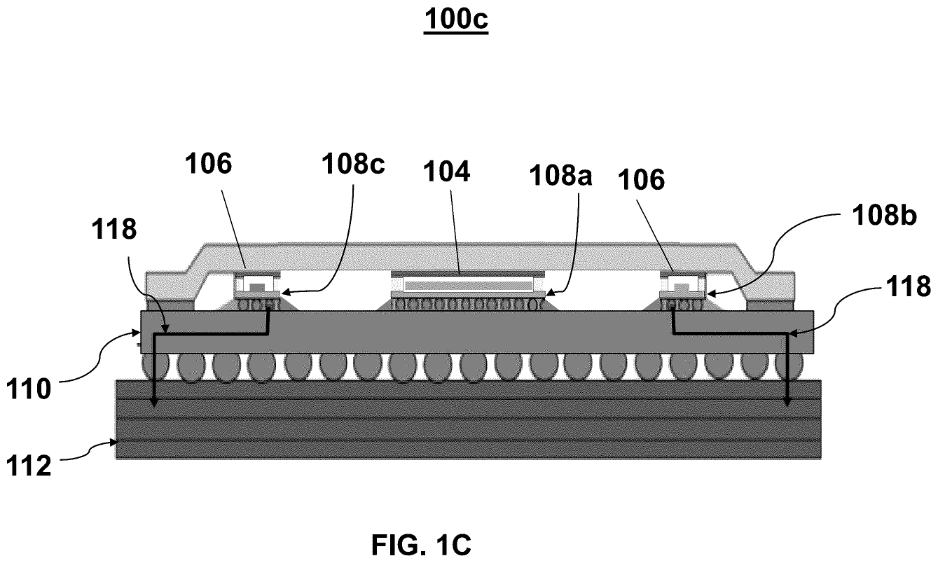

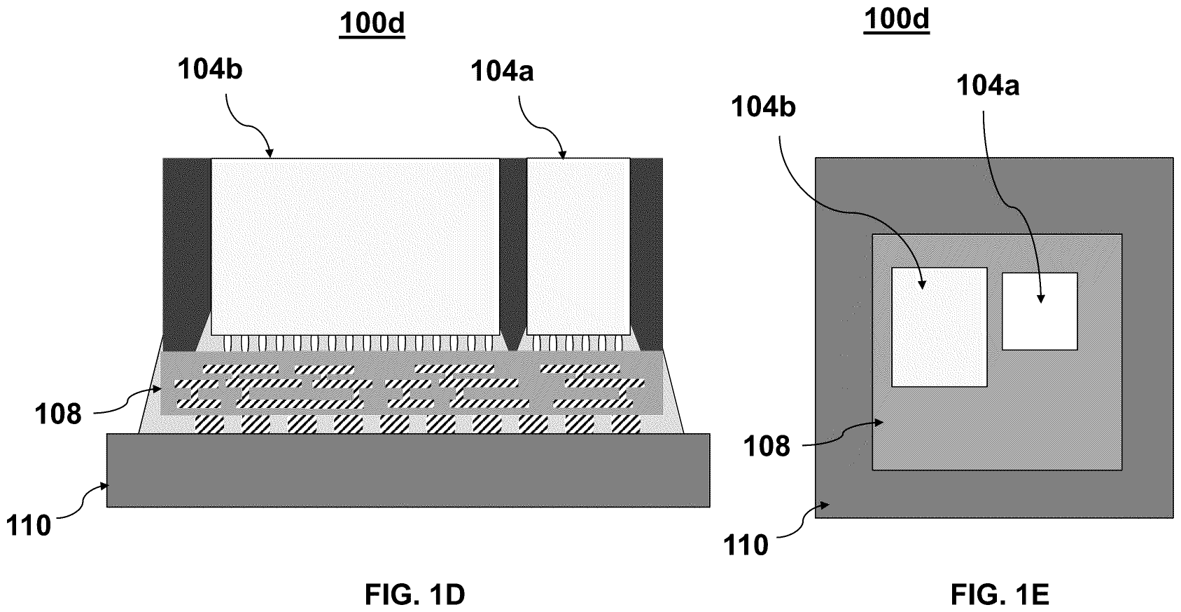

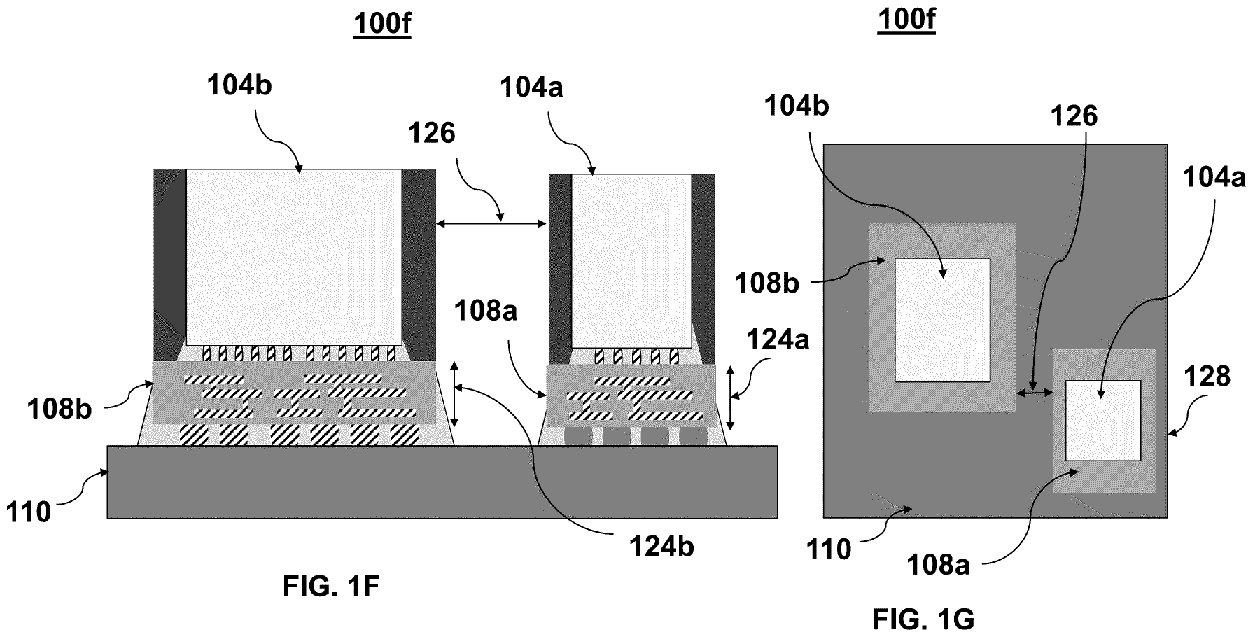

FIG. 1A is a vertical cross-sectional view of an exemplary semiconductor device 100a structure. The conventional semiconductor device structure 100a includes an integrated device die 102 that includes a semiconductor device die 104 integrated with a device die 106. The integrated device die 102 may be coupled to an interposer 108, which may be coupled to a package substrate 110. The package substrate 110 may further be coupled to a printed circuit board (PCB) 112. The interposer 108 may be bonded to the package substrate 110 through first solder material portions 114a that bond respective bump structures (not shown) on the interposer 108 and on the package substrate 110. Similarly, the package substrate 110 may be bonded to the printed circuit board 112 through second solder material portions 114b that bond respective bump structures (not shown) on the package substrate 110 and printed circuit board 112.

The semiconductor device structure 100a may further include a package lid 116 attached to the package substrate 110 and covering the integrated device die 102 and interposer 108. The package substrate 110 includes redistribution interconnect structures that include various electrical pathways 118. The electrical pathways 118 may be configured to electrically connect the integrated device die 102 to neighboring semiconductor device structures (not shown) that may be located on neighboring interposers (not shown) attached to the package substrate 110. Each of the various electrical pathways 118 includes an associated impedance. As such, the long length of the conventional electrical pathways 118 leads to ohmic losses and RC delays.

FIG. 1B is a vertical cross-sectional view of a further exemplary semiconductor device structure 100b. In contrast to the integrated device structure 102 of FIG. 1A, in this example, the traditional semiconductor device die 104 and the serializer/de-serializer device die 106 may be formed as separate structures. As such, electrical pathways 118 that connect the serializer/de-serializer device die 106 to the package substrate 110 and to the printed circuit board 112 may be reduced in length, thereby reducing ohmic losses and RC delays. Semiconductor device structure 100b includes a larger interposer 108 that allows the serializer/de-serializer device die 106 to be placed proximate to sidewalls of the package substrate 110. However, the use of a traditional larger interposer 108 increases the complexity and length of redistribution interconnect structures (not shown) within the interposer 108. Further, a larger package lid 116 is applied for covering a larger interposer 108. Additional structural support structures 120 (i.e., one or more “dummy dies” 120) is therefore included to ensure that the larger package lid 116 is mechanically secure. The support structures 120 are optional and may allow an increase in die to die interconnect routing density. Routing density may also be increased in other ways, for example, by increasing the number of redistribution layers and by decreasing a pitch of redistribution layer fine lines.

FIG. 1C is a vertical cross-sectional view of a further exemplary semiconductor device structure 100c, according to various embodiments. The semiconductor device structure 100c includes a semiconductor device die 104 and a serializer/de-serializer device die 106 respectively formed on separate interposers 108a, 108b, and 108c. As in the embodiment described above with reference to FIG. 1B, the semiconductor device structure 100c may exhibit reduced impedance by placing the serializer/de-serializer device die 106 closer to sidewalls of the package substrate 110. In this way, the length of electrical pathways 118 between the serializer/de-serializer device die 106 and the printed circuit board 112 may be reduced. In contrast to the semiconductor device structure 100b of FIG. 1B, however, the use of a larger interposer 108 is avoided, in the example of FIG. 1C, by using separate smaller interposers 108a, 108b, and 108c. The use of separate smaller interposers 108a, 108b, and 108c may also increase design flexibility with regard to die placement and may avoid the complexity and increased impedance associated with a larger interposer 108, such as the larger interposer 108 described above with reference to FIG. 1B.

FIGS. 1D to 1G illustrate details of exemplary semiconductor device structures having two semiconductor device dies on a single interposer (e.g., FIGS. 1D and 1E) in contrast to exemplary semiconductor device structures having two semiconductor device dies on two respective interposers (e.g., FIGS. 1F and 1G), according to various embodiments.

FIG. 1D is a vertical cross-sectional view of an exemplary semiconductor device structure 100d having two semiconductor device dies on a single interposer 108, according to various embodiments. In this regard, the semiconductor device structure 100d of FIG. 1D includes a first semiconductor device die 104a and a second semiconductor device die 104b. The first semiconductor device die 104a and the second semiconductor device die 104b may both be coupled to a single interposer 108. The interposer 108 may be coupled to a package substrate 110. An interposer 108 that is large enough to accommodate both the first semiconductor device die 104a and the second semiconductor device die 104b, however, may have increased impedance and corresponding ohmic loss and RC delay relative to smaller interposers, such as the first interposer 108a and the second interposer 108b, described with reference to FIGS. 1F and 1G, below.

FIG. 1E is a plan view of the exemplary semiconductor device structure 100d of FIG. 1D, according to various embodiments. As shown in FIG. 1E, for example, the interposer 108, of semiconductor device structure 100d covers a certain area over the package substrate 110. The first semiconductor device die 104a and the second semiconductor device die 104b may be constrained to reside within the area spanned by the interposer 108. Further, as described above, the use of a large interposer 108 to accommodate both the first semiconductor device die 104a and the second semiconductor device die 104b may have drawbacks in terms of longer electrical pathways 118 (e.g., see FIG. 1A) having increased impedance.

FIG. 1F is a vertical cross-sectional view of an exemplary semiconductor device structure 100f having two semiconductor device dies on two respective interposers 108a, 108b, according to various embodiments. In this regard, a first semiconductor device die 104a may be coupled to a first interposer 108a, which may be coupled to a package substrate 110. Similarly, a second semiconductor device die 104b may be coupled to a second interposer 108b, which may be coupled to the package substrate 110. The first semiconductor device die 104a may be a SoC die, an HBM die, an integrated passive device (IPD) die, etc. Similarly, the second semiconductor device die 104b may be a SoC die, an HBM die, an integrated passive device (IPD) die, etc. In further embodiments, one of the first semiconductor device die 104a and the second semiconductor device die 104b may be a serializer/de-serializer device die 106 (e.g., see FIGS. 1A to 1C and related description, above).

The first interposer 108a may have a first thickness 124a and the second interposer 108b may have a second thickness 124b. The first interposer 108a may be an organic interposer, a silicon interposer, or may be a hybrid organic/silicon interposer. Similarly, the second interposer 108b may be an organic interposer, a silicon interposer, or may be a hybrid organic/silicon interposer. The first interposer 108a and the second interposer 108b may be separated by a first distance 126. In certain embodiments, the first distance 126 separating the first interposer 108a and the second interposer 108b may be greater than or equal to approximately 2 mm.

FIG. 1G is a plan view of the exemplary semiconductor device structure 100f of FIG. 1F, according to various embodiments. As shown in FIG. 1G, for example, the first interposer 108a may have a first area and the second interposer 108b may have a second area. Further, the use of separate, smaller interposers provides greater flexibility with regard to the placement of the first semiconductor device die 104a and the second semiconductor device die 104b. For example, in certain embodiments, the first semiconductor device die 104a may be a serializer/de-serializer device die 106 (e.g., see FIGS. 1A to 1C and related description, above) that may be placed at the peripheral region (proximate to a sidewall 128) of the package substrate 110. As described with reference to FIG. 1C, above, placement of the serializer/de-serializer device die 106 (e.g., see FIG. 1C and related description, above) may allow electrical pathways 118 to have reduced length. Such electrical pathways 118 with a reduced length may have reduced impedance and RC delays. As such, embodiments having semiconductor device dies 104 coupled to separate, smaller, interposers 108 (e.g., see FIGS. 1C, 1F, and 1G) may be more suitable than embodiments having multiple semiconductor device dies 104 on a single larger interposer (e.g., see FIG. 1B). In general, a semiconductor die (104a, 104b) may be placed within a distance that is less than 1000 microns from an edge of a respective interposer (108a, 108b). For example, in some embodiments, a semiconductor die (104a, 104b) may be placed within a distance that is less than 500 microns from an edge of a respective interposer (108a, 108b).

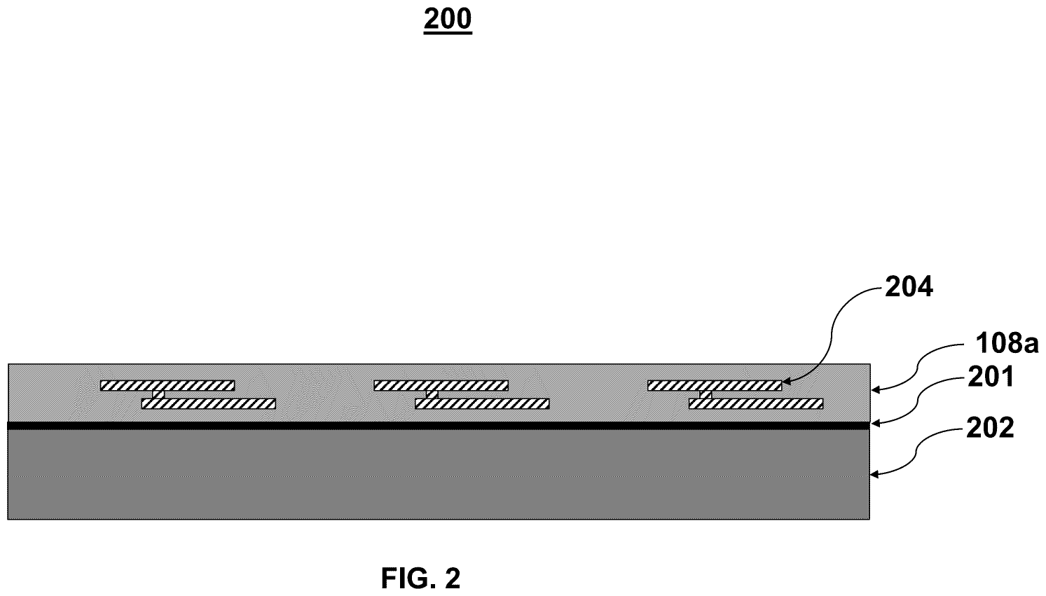

FIG. 2 is a vertical cross-sectional view of an intermediate structure 200 used in the formation of a plurality of chiplets, according to various embodiments. In this regard, the structure 200 may include an interposer 108a formed over a carrier substrate 202. The interposer 108a may be an organic interposer or a silicon interposer.

The carrier substrate 202 may include a semiconductor substrate, an insulating substrate, or a conductive substrate. The carrier substrate 202 may be transparent or opaque. The carrier substrate 202 may have a thickness that is sufficient to provide mechanical support to an array of interposers 108a to be subsequently formed thereupon. For example, the carrier substrate 202 may have a thickness in a range from approximately 60 microns to approximately 1 mm. Alternative embodiments may include carrier substrates having a larger or smaller thickness.

The intermediate structure 200 of FIG. 2 may include an adhesive layer 201 applied to a top surface of the carrier substrate 202. In various embodiments, the carrier substrate 202 may include an optically transparent material such as glass or sapphire. In this example, the adhesive layer 201 may include a light-to-heat conversion (LTHC) layer. The LTHC layer may be a solvent-based coating applied using a spin coating method. The LTHC layer may form a layer that converts ultraviolet light to heat such that the LTHC layer loses adhesion. Alternatively, the adhesive layer 201 may include an adhesive material that is configured to be thermally decomposed. For example, the adhesive layer 201 may include an acrylic pressure-sensitive adhesive that decomposes at an elevated temperature. The thermally decomposing adhesive material may have a debonding temperature that is in a range from approximately 150° F. to approximately 400° F. Other suitable thermally decomposing adhesive materials that decompose at other temperatures are within the contemplated scope of disclosure.

The interposer 108 may include various redistribution interconnect structures 204 that include multiple levels of redistribution interconnect structures 204 that may be formed within a dielectric material. In embodiments in which the interposer 108a is an organic interposer, the dielectric material may include a plurality of dielectric layers (not shown explicitly) including a dielectric polymer material such as polyimide, benzocyclobutene, or polybenzobisoxazole. Other suitable materials are within the contemplated scope of disclosure. The thickness of each interconnect-level polymer matrix layer may be in a range from approximately 4 microns to approximately 20 microns, although alternative embodiments may include smaller or larger thicknesses. Silicon interposers 108a, in various embodiments, may include a silicon substrate supporting the redistribution interconnect structures 204.

The redistribution interconnect structures 204 may include metal via structures, metal line structures, and/or integrated line and via structures. Each integrated line and via structure includes a unitary structure containing a metal line structure and at least one metal via structure. A unitary structure refers to a single continuous structure in which each point within the structure may be connected by a continuous line (which may or may not be straight) that may extend only within the structure.

The redistribution interconnect structures 204 may include at least one metallic material such as Cu, Mo, Co, Ru, W, TiN, TaN, WN, or a combination or a stack thereof. Other suitable materials are within the contemplated scope of this disclosure. For example, each of the redistribution interconnect structures 204 may include a layer stack of a TiN layer and a Cu layer. In embodiments in which a redistribution interconnect structure 204 includes a metal line structure, a thickness of the metal line structure may be in a range from approximately 2 microns to approximately 20 microns, although alternative embodiments may include smaller or larger thicknesses.

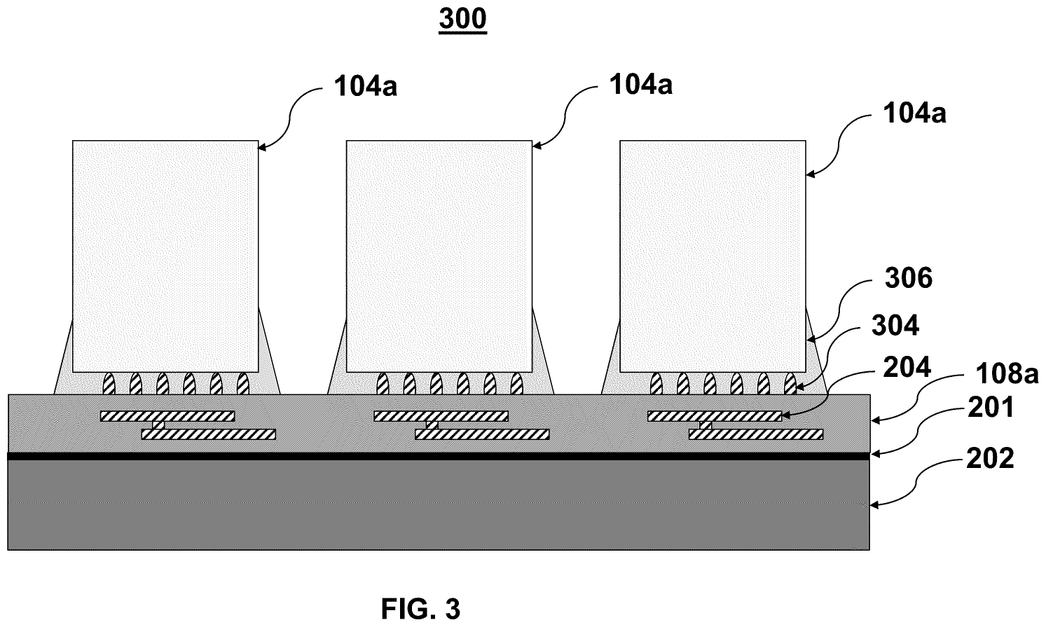

FIG. 3 is a vertical cross-sectional view of a further intermediate structure 300 used in the formation of a plurality of chiplets, according to various embodiments. In this regard, a plurality of semiconductor device dies 104a may be coupled to the interposer 108. Each of the semiconductor device dies 104a may be a SoC die, an HBM die, an IPD die, etc. In further embodiments, each of the semiconductor device dies 104a may be a serializer/de-serializer device die 106 (e.g., see FIGS. 1A to 1C and related description, above). Each of the semiconductor device dies 104a may be attached to die-side bump structures (not shown) of the interposer 108a through at least one array of first solder material portions 304.

At least one underfill material portion 306 may be formed around each bonded array of first solder material portions 304. Each underfill material portion 306 may be formed by injecting an underfill material around the array of first solder material portions 304 after the first solder material portions 304 are reflowed. Various underfill material application methods may be used, which may include, for example, a capillary underfill method, a molded underfill method, or a printed underfill method.

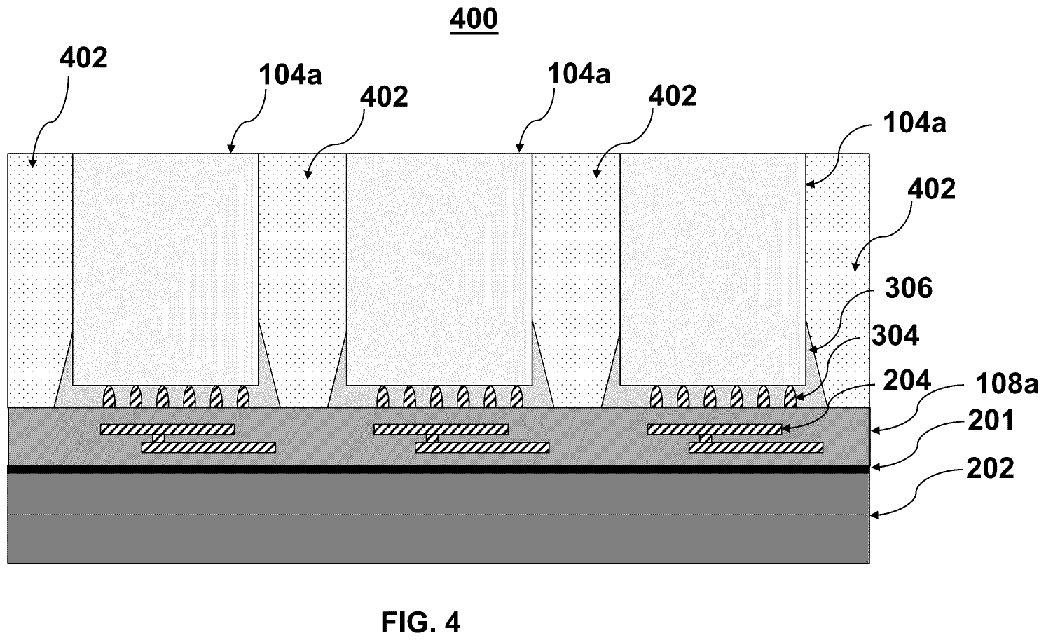

FIG. 4 is a vertical cross-sectional view of a further intermediate structure 400 used in the formation of a plurality of chiplets, according to various embodiments. Structure 400 may include an epoxy molding compound (EMC) 402 that may be applied to gaps formed between the interposer 108a and the semiconductor device dies 104a. The EMC 402 may include an epoxy-containing compound that may be hardened (i.e., cured) to provide a dielectric material portion having sufficient stiffness and mechanical strength. The EMC 402 may include epoxy resin, hardener, silica (as a filler material), and other additives. The EMC 402 may be provided in a liquid form or in a solid form depending on the viscosity and flowability.

Liquid EMC 402 may provide better handling, good flowability, fewer voids, better fill, and fewer flow marks. Solid EMC 402 provides less cure shrinkage, better stand-off, and less die drift. A high filler content (such as 85% in weight) within an EMC 402 may shorten the time in mold, lower the mold shrinkage, and reduce the mold warpage. A uniform filler size distribution in the EMC 402 may reduce flow marks, and may enhance flowability. The curing temperature of the EMC 402 may be lower than the release (debonding) temperature of the adhesive layer 201. For example, the curing temperature of the EMC 402 may be in a range from 125° C. to 150° C.

The EMC 402 may be cured at a curing temperature to form an EMC matrix that laterally encloses each of the semiconductor device dies 104a. The EMC matrix may include a plurality of epoxy molding compound (EMC) frames that may be laterally adjoined to one another. Each EMC die frame laterally surrounds and embeds a respective one of the semiconductor device dies 104a. Excess portions of the EMC 402 may be removed from above the horizontal plane including the top surfaces of the semiconductor device dies 104a by a planarization process, such as chemical mechanical planarization (CMP).

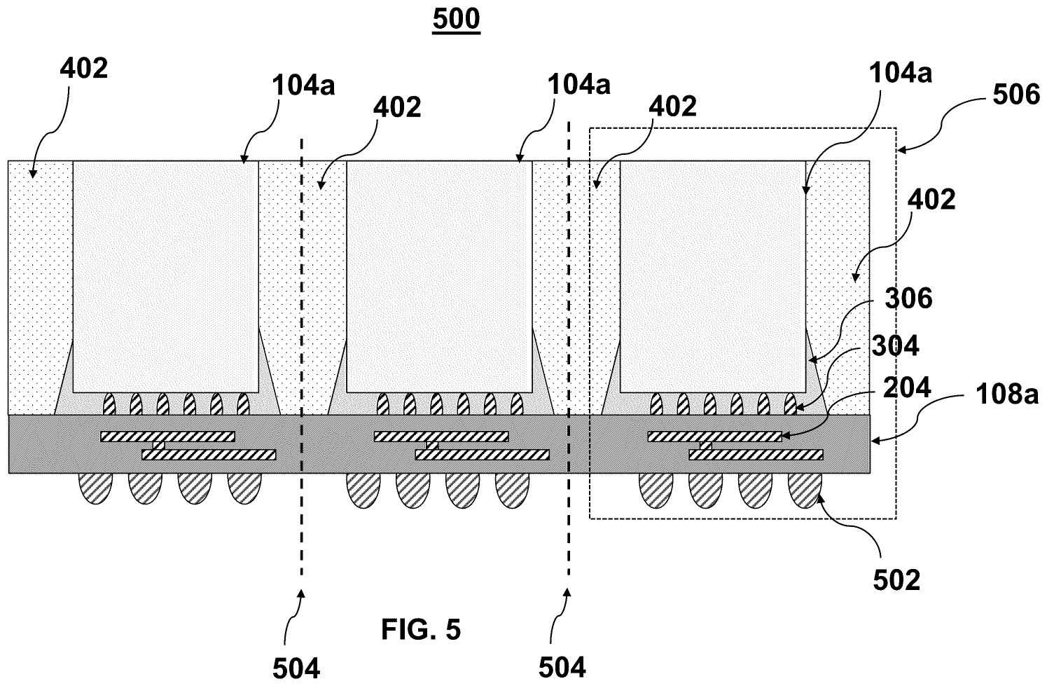

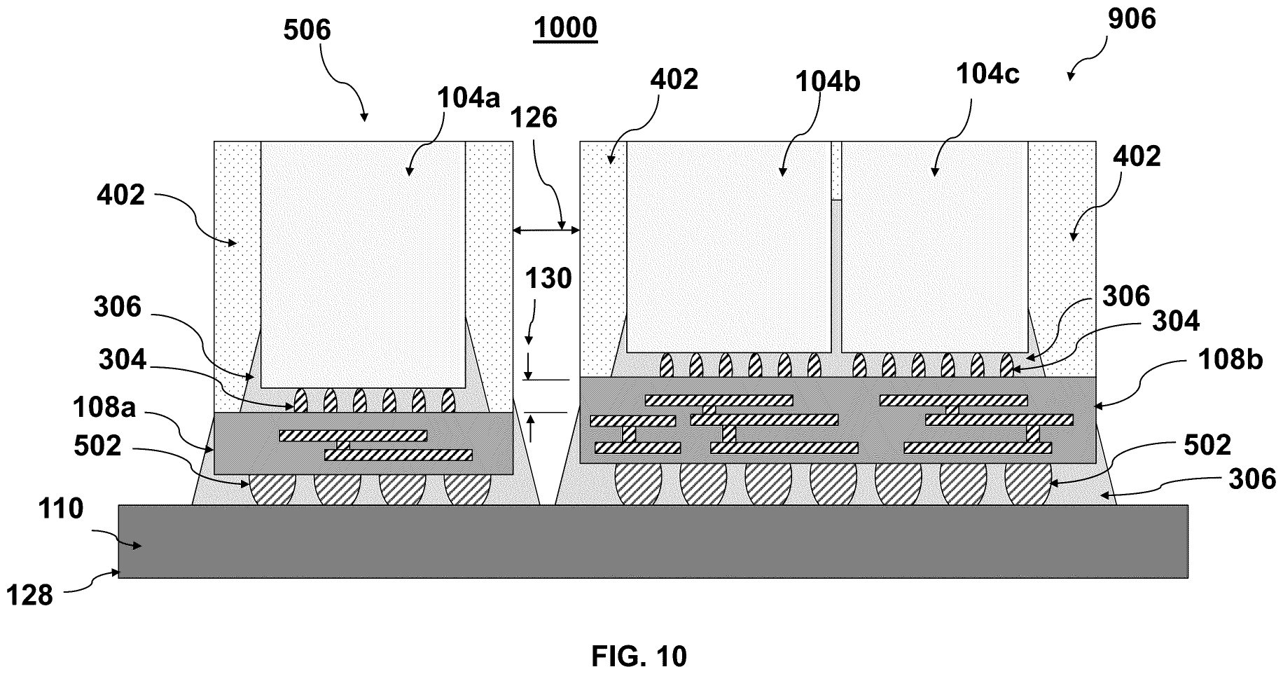

FIG. 5 is a vertical cross-sectional view of a further intermediate structure 500 used in the formation of a plurality of chiplets, according to various embodiments. The carrier substrate 202 (e.g., see FIGS. 2 to 4) may be detached from the assembly of the interposer 108a, the semiconductor device dies 104a, and the EMC 402 die frames. In this regard, the adhesive layer 201 may be deactivated, for example, by a thermal anneal at an elevated temperature. Embodiments may include an adhesive layer 201 that includes a thermally-deactivated adhesive material. In other embodiments in which the carrier substrate 202 may be transparent, an adhesive layer 201 may include an ultraviolet-deactivated adhesive material. Second solder material portions 502 may be formed on bump structures (not shown) on a package-side of the interposer 108a. Individual first chiplets 506 may then be formed by dicing the assembly of the interposer 108a, the semiconductor device dies 104a, and the EMC 402 die frames along scribe lines 504. Individual first chiplets 506 may then be attached to a package substrate 110, as described in greater detail with reference to FIGS. 10 to 12, below.

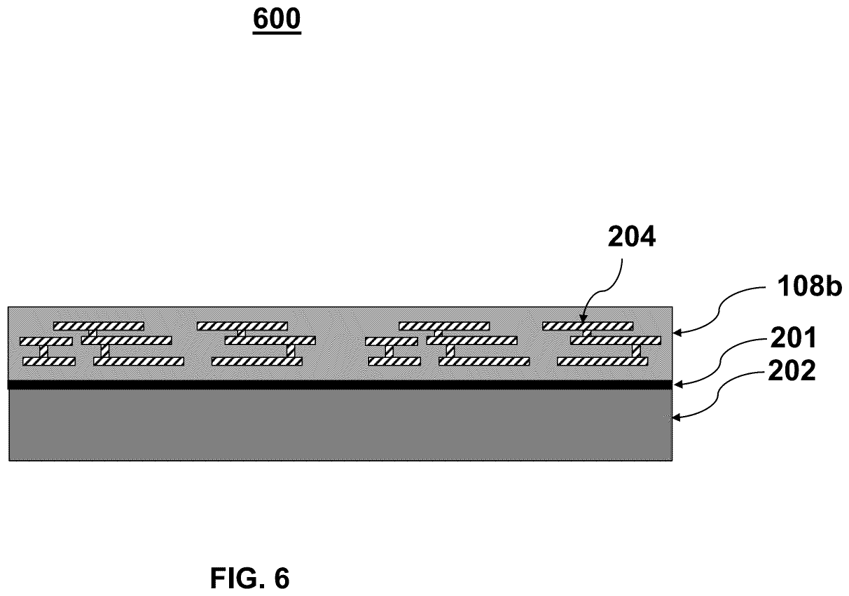

FIG. 6 is a vertical cross-sectional view of an intermediate structure 600 used in the formation of a plurality of chiplets, according to various embodiments. In this regard, the structure 600 may include an interposer 108b formed over a carrier substrate 202. The interposer 108b may be an organic interposer or a silicon interposer.

The carrier substrate 202 may include a semiconductor substrate, an insulating substrate, or a conductive substrate. The carrier substrate 202 may be transparent or opaque. The carrier substrate 202 may have a thickness that is sufficient to provide mechanical support to an array of interposers 108b to be subsequently formed thereupon. For example, the carrier substrate 202 may have a thickness in a range from approximately 60 microns to approximately 1 mm. Alternative embodiments may include carrier substrates having a larger or smaller thickness.

The intermediate structure 600 of FIG. 6 may include an adhesive layer 201 applied to a top surface of the carrier substrate 202. In various embodiments, the carrier substrate 202 may include an optically transparent material such as glass or sapphire. In this example, the adhesive layer 201 may include a light-to-heat conversion (LTHC) layer. The LTHC layer may be a solvent-based coating applied using a spin coating method. The LTHC layer may form a layer that converts ultraviolet light to heat such that the LTHC layer loses adhesion. Alternatively, the adhesive layer 201 may include an adhesive material that is configured to be thermally decomposed. For example, the adhesive layer 201 may include an acrylic pressure-sensitive adhesive that decomposes at an elevated temperature. The thermally decomposing adhesive material may have a debonding temperature that is in a range from approximately 150° F. to approximately 400° F. Other suitable thermally decomposing adhesive materials that decompose at other temperatures are within the contemplated scope of disclosure.

The interposer 108b may include various redistribution interconnect structures 204 that include multiple levels of redistribution interconnect structures 204 that are formed within a dielectric material. In embodiments in which the interposer 108b is an organic interposer, the dielectric material may include a plurality of dielectric layers (not shown explicitly) including a dielectric polymer material such as polyimide, benzocyclobutene, or polybenzobisoxazole. Other suitable materials are within the contemplated scope of disclosure. The thickness of each interconnect-level polymer matrix layer may be in a range from approximately 4 microns to approximately 20 microns, although alternative embodiments may include smaller or larger thicknesses. Silicon interposers 108b, in various embodiments, may include a silicon substrate supporting the redistribution interconnect structures 204.

The redistribution interconnect structures 204 may include metal via structures, metal line structures, and/or integrated line and via structures. Each integrated line and via structure includes a unitary structure containing a metal line structure and at least one metal via structure. A unitary structure refers to a single continuous structure in which each point within the structure may be connected by a continuous line (which may or may not be straight) that may extend only within the structure.

The redistribution interconnect structures 204 may include at least one metallic material such as Cu, Mo, Co, Ru, W, TiN, TaN, WN, or a combination or a stack thereof. Other suitable materials are within the contemplated scope of this disclosure. For example, each of the redistribution interconnect structures 204 may include a layer stack of a TiN layer and a Cu layer. In embodiments in which a redistribution interconnect structure 204 includes a metal line structure, a thickness of the metal line structure may be in a range from approximately 2 microns to approximately 20 microns, although alternative embodiments may include smaller or larger thicknesses.

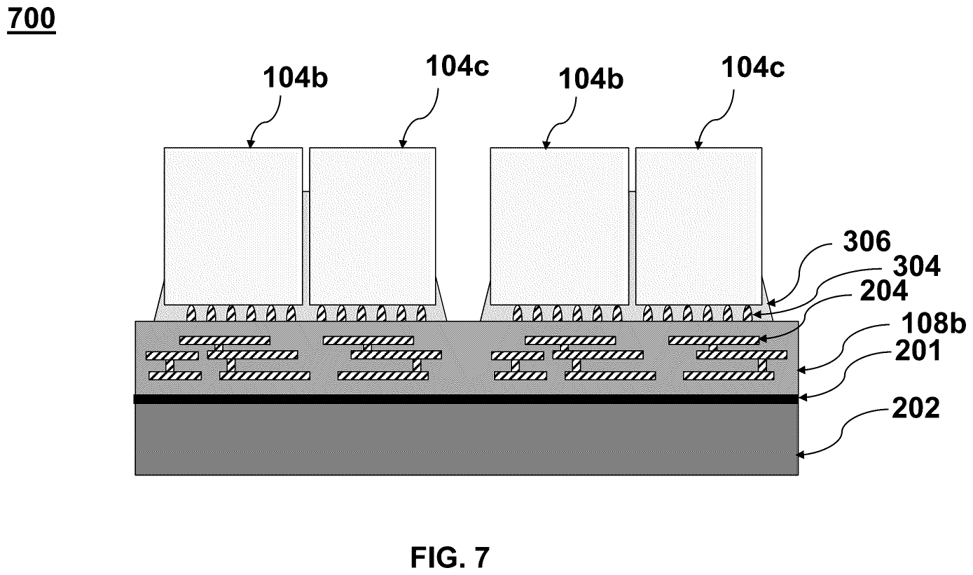

FIG. 7 is a vertical cross-sectional view of a further intermediate structure 700 used in the formation of a plurality of chiplets, according to various embodiments. In this regard, a plurality of second semiconductor device dies 104b and third semiconductor device dies 104c may be coupled to the interposer 108b. Each of the second semiconductor device dies 104b and third semiconductor device dies 104c may be a SoC die, an HBM die, an IPD die, etc. In further embodiments, each of the second semiconductor device dies 104b may be SoC die, and each of the third semiconductor device dies 104c may be an HBM die. Each of the second semiconductor device dies 104b and third semiconductor device dies 104c may be attached to die-side bump structures (not shown) of the interposer 108b through at least one array of first solder material portions 304.

At least one underfill material portion 306 may be formed around each bonded array of first solder material portions 304. Each underfill material portion 306 may be formed by injecting an underfill material around the array of first solder material portions 304 after the first solder material portions 304 are reflowed. Various underfill material application methods may be used, which may include, for example, a capillary underfill method, a molded underfill method, or a printed underfill method.

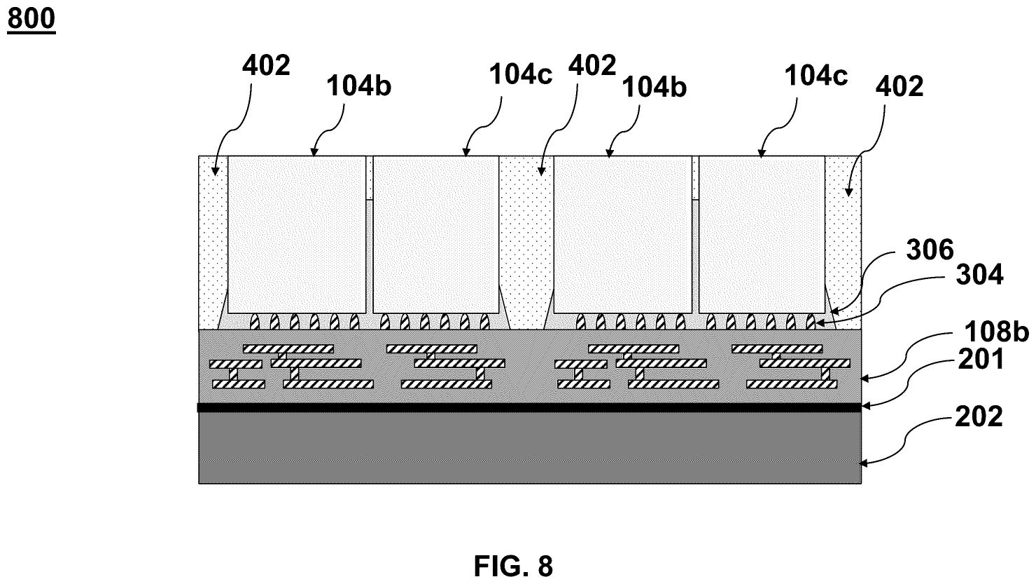

FIG. 8 is a vertical cross-sectional view of a further intermediate structure 800 used in the formation of a plurality of chiplets, according to various embodiments. Structure 800 may include an EMC 402 that may be applied to gaps formed between the interposer 108b and the second semiconductor device dies 104b and third semiconductor device dies 104c. The EMC 402 may include an epoxy-containing compound that may be hardened (i.e., cured) to provide a dielectric material portion having sufficient stiffness and mechanical strength. The EMC 402 may include epoxy resin, hardener, silica (as a filler material), and other additives. The EMC 402 may be provided in a liquid form or in a solid form depending on the viscosity and flowability.

Liquid EMC 402 may provide better handling, good flowability, fewer voids, better fill, and fewer flow marks. Solid EMC 402 provides less cure shrinkage, better stand-off, and less die drift. A high filler content (such as 85% in weight) within an EMC 402 may shorten the time in mold, lower the mold shrinkage, and reduce the mold warpage. Uniform filler size distribution in the EMC 402 may reduce flow marks, and may enhance flowability. The curing temperature of the EMC 402 may be lower than the release (debonding) temperature of the adhesive layer 201. For example, the curing temperature of the EMC 402 may be in a range from 125° C. to 150° C.

The EMC 402 may be cured at a curing temperature to form an EMC matrix that laterally encloses each of the second semiconductor device dies 104b and third semiconductor device dies 104c. The EMC matrix may include a plurality of EMC frames that are laterally adjoined to one another. Each EMC die frame laterally surrounds and embeds a respective one of the second semiconductor device dies 104b and third semiconductor device dies 104c. Excess portions of the EMC 402 may be removed from above the horizontal plane including the top surfaces of the second semiconductor device dies 104b and third semiconductor device dies 104c by a planarization process, which may use chemical mechanical planarization.

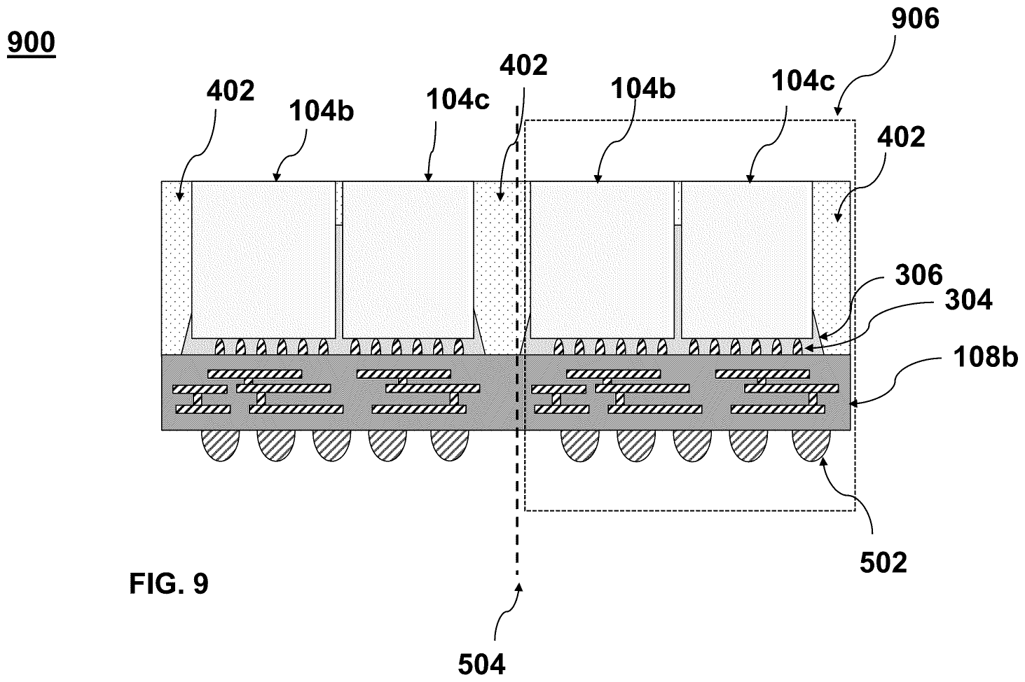

FIG. 9 is a vertical cross-sectional view of a further intermediate structure 900 used in the formation of a plurality of chiplets, according to various embodiments. The carrier substrate 202 (e.g., see FIGS. 6 to 8) may be detached from the assembly of the interposer 108, the second semiconductor device dies 104b and third semiconductor device dies 104c, and the EMC 402 die frames. In this regard, the adhesive layer 201 may be deactivated, for example, by a thermal anneal at an elevated temperature. Embodiments may include an adhesive layer 201 that includes a thermally-deactivated adhesive material. In other embodiments in which the carrier substrate 202 may be transparent, an adhesive layer 201 may include an ultraviolet-deactivated adhesive material. Second solder material portions 502 may be formed on bump structures (not shown) on a package-side of the interposer 108b. Individual second chiplets 906 may then be formed by dicing the assembly of the second interposer 108b, the second semiconductor device dies 104b and third semiconductor device dies 104c, and the EMC 402 die frames along scribe lines 504. Individual second chiplets 906 may then be attached to a package substrate 110, as described in greater detail with reference to FIGS. 10 to 12, below.

FIG. 10 is a vertical cross-sectional view of a system 1000 having a first chiplet 506 and a second chiplet 906 attached to a package substrate 110, according to various embodiments. The first chiplet 506 may include a first semiconductor device die 104a attached to a first interposer 108a. The first chiplet 506 may be fabricated according to the methods described above with reference to FIGS. 2 to 5. The second chiplet 906 may include a second semiconductor device die 104b and a third semiconductor device die 104c. The second semiconductor device die 104b and the third semiconductor device die 104c may each be attached to a second interposer 108b. The second chiplet 906 may be fabricated according to the methods described above with reference to FIGS. 6 to 9.

Each of the first chiplet 506 and the second chiplet 906 may be attached to bump structures (not shown) on the package substrate 110 through the second solder portions 502. At least one underfill material portion 306 may be formed around each bonded array of second solder material portions 502. Each underfill material portion 306 may be formed by injecting an underfill material around the array of second solder material portions 502 after the second solder material portions 502 are reflowed. Various underfill material application methods may be used, which may include, for example, a capillary underfill method, a molded underfill method, or a printed underfill method.

In this embodiment, the first semiconductor device die 104a, located on the first chiplet 506, may be a serializer/de-serializer device die 106 (e.g., see FIGS. 1A to 1C and related description, above). Further, the first semiconductor device die 104a may be located proximate to the sidewall 128 of the package substrate 110, as described above with reference to FIG. 1G. The second semiconductor device die 104b, located on the second chiplet 906, may be a SoC die and the third semiconductor device die 104c, located on the second chiplet 906, may be an HBM die.

The first interposer 108a and the second interposer 108b may be separated by a first distance 126, as described above with reference to FIGS. 1F and 1G. In certain embodiments, the first distance 126 separating the first interposer 108a and the second interposer 108b may be greater than or equal to approximately 2 mm. The first interposer 108a and the second interposer 108b may each be an organic interposer, a silicon interposer, or a hybrid organic/silicon interposer. In this example embodiment, both of the first interposer 108a and the second interposer 108b are organic interposers although they may not have the same dimensions. In this regard, as shown in FIG. 10, there may be a difference in height between the first interposer 108a and the second interposer 108b. In in this example, a top surface of the second interposer 108b may be higher than a top surface of the first interposer 108a by a second distance 130. In other embodiments, the first interposer 108a and the second interposer 108b may have top surfaces that are aligned, while in still other embodiments the first interposer 108a may have a top surface that is higher than the top surface of the second interposer 108b.

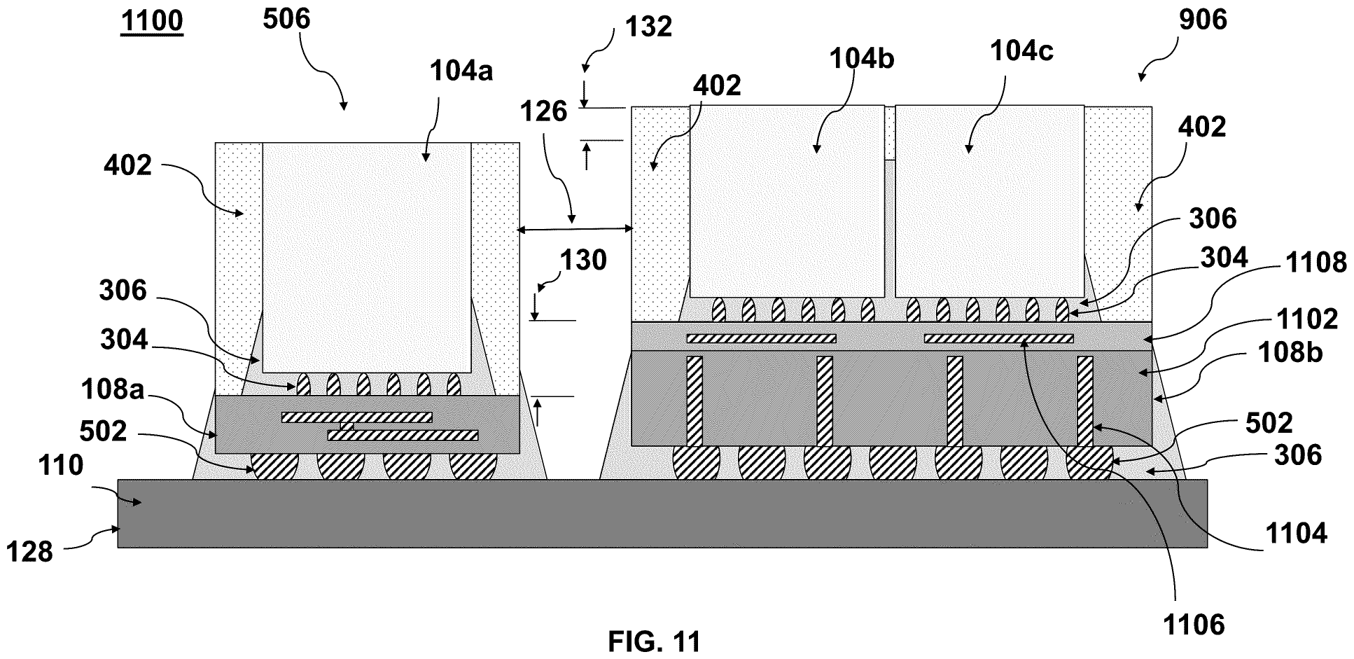

FIG. 11 is a vertical cross-sectional view of a further system 1100 having a first chiplet and a second chiplet attached to a package substrate 110, according to various embodiments. The first chiplet 506 may include a first semiconductor device die 104a attached to a first interposer 108a. As with the system 1000 of FIG. 10, the first chiplet 506 may be fabricated according to the methods described above with reference to FIGS. 2 to 5. The second chiplet 906 may include a second semiconductor device die 104b and a third semiconductor device die 104c. The second semiconductor device die 104b and the third semiconductor device die 104c may each be attached to a second interposer 108b. The second chiplet 906 may be fabricated according to the methods described above with reference to FIGS. 6 to 9.

Each of the first chiplet 506 and the second chiplet 906 may be attached to bump structures (not shown) on the package substrate 110 through the second solder portions 502. At least one underfill material portion 306 may be formed around each bonded array of second solder material portions 502. Each underfill material portion 306 may be formed by injecting an underfill material around the array of second solder material portions 502 after the second solder material portions 502 are reflowed. Various underfill material application methods may be used, which may include, for example, a capillary underfill method, a molded underfill method, or a printed underfill method.

In this embodiment, the first semiconductor device die 104a, located on the first chiplet 506, may be a serializer/de-serializer device die 106 (e.g., see FIGS. 1A to 1C and related description, above). Further, the first semiconductor device die 104a may be located proximate to the sidewall 128 of the package substrate 110, as described above with reference to FIGS. 1G and 10. The second semiconductor device die 104b, located on the second chiplet 906, may be a SoC die and the third semiconductor device die 104c, located on the second chiplet 906, may be an HBM die.

The first interposer 108a and the second interposer 108b may be separated by a first distance 126, as described above with reference to FIGS. 1F, 1G, and 10. In certain embodiments, the first distance 126 separating the first interposer 108a and the second interposer 108b may be greater than or equal to approximately 2 mm. Further, as shown in FIG. 10, there may be a difference in height between the first interposer 108a and the second interposer 108b. In in this example, a top surface of the second interposer 108b is higher than a top surface of the first interposer 108a by a second distance 130. In other embodiments, the first interposer 108a and the second interposer 108b may have top surfaces that are aligned, while in still other embodiments the first interposer 108a may have a top surface that is higher than the top surface of the second interposer 108b.

In this example embodiment, the first chiplet 506 and the second chiplet 906 may have unequal heights. As shown in FIG. 11, the second chiplet 906 may have a top surface that is higher than a top surface of the first chiplet 506 by a third distance 132. In other embodiments, the first chiplet 506 and the second chiplet 906 may have equal heights, as in the example system 1000 described above with reference to FIG. 10. In still further embodiments, the first chiplet 506 may have a top surface that is higher than the top surface of the second chiplet 906.

In this example embodiment, the first interposer 108a may be an organic interposer and the second interposer 108b may be a silicon interposer. The silicon interposer may include a silicon substrate 1102, through-substrate via (TSV) structures 1104, and metal interconnect structures 1106 embedded in dielectric material layers 1108. The silicon interposer may provide vertical signal paths that include the TSV structures and horizontal interconnection paths that include metal the interconnect structures 1106 embedded in the dielectric material layers 1108. The TSV structures may be provided in a high density array configuration to provide wide bandwidth connections between semiconductor dies and the package substrate 110. The metal interconnect structures 1106 may be configured to provide high bandwidth chip-to-chip signal paths to and from multiple semiconductor chips (e.g., between the second semiconductor device die 104b and the third semiconductor device die 104c). The interposer structure may be used to provide high-speed high-bandwidth interconnections to and from semiconductor dies (e.g., the second semiconductor device die 104b and the third semiconductor device die 104c) and between the semiconductor dies and the package substrate 110.

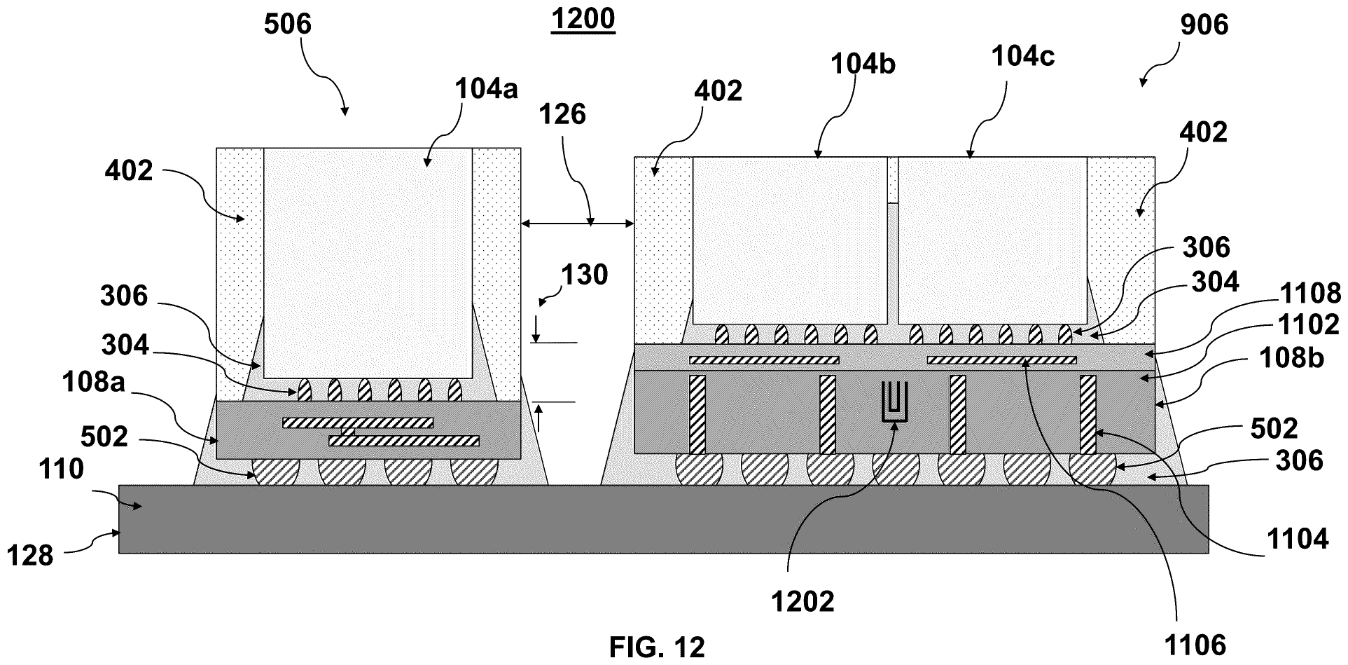

FIG. 12 is a vertical cross-sectional view of a further system 1200 having a first chiplet 506 and a second chiplet 906 attached to a package substrate 110, according to various embodiments. As with the systems 1000 of FIGS. 10 and 1100 of FIG. 11, the first chiplet 506 may be fabricated according to the methods described above with reference to FIGS. 2 to 5 and the second chiplet 906 may be fabricated according to the methods described above with reference to FIGS. 6 to 9. In this embodiment, the first semiconductor device die 104a, located on the first chiplet 506, may be a serializer/de-serializer device die 106 (e.g., see FIGS. 1A to 1C and related description, above). Further, the first semiconductor device die 104a may be located proximate to the sidewall 128 of the package substrate 110, as described above with reference to FIGS. 1G, 10, and 11. The second semiconductor device die 104b, located on the second chiplet 906, may be a SoC die and the third semiconductor device die 104c, located on the second chiplet 906, may be an HBM die.

The first interposer 108a and the second interposer 108b may be separated by a first distance 126, as described above with reference to FIGS. 1F, 1G, 10, and 11. Further, as shown in FIGS. 10 and 11, there may be a difference in height between the first interposer 108a and the second interposer 108b. In in this example, a top surface of the second interposer 108b is higher than a top surface of the first interposer 108a by a second distance 130. In other embodiments, the first interposer 108a and the second interposer 108b may have top surfaces that are aligned, while in still other embodiments the first interposer 108a may have a top surface that is higher than the top surface of the second interposer 108b.

In this example embodiment, the first interposer 108a may be an organic interposer and the second interposer 108b may be a silicon interposer. The silicon interposer may include a silicon substrate 1102, TSV structures 1104, and metal interconnect structures 1106 embedded in dielectric material layers 1108. In addition, the second interposer 108b may further include one or more passive device structures. For example, the second interposer 108b may include a deep trench capacitor 1202 having a capacitance C. In other embodiments, the second interposer 108b may include various other passive elements including at least one inductor, at least one resistor, at least one diode, at least one antenna, or any other passive electrical component. The deep trench capacitor 1202 may be electrically connected to metal interconnect structures 1106 and TSV structures 1104. The presence of various passive elements (e.g., deep trench capacitor 1202) may increase circuit design flexibility.

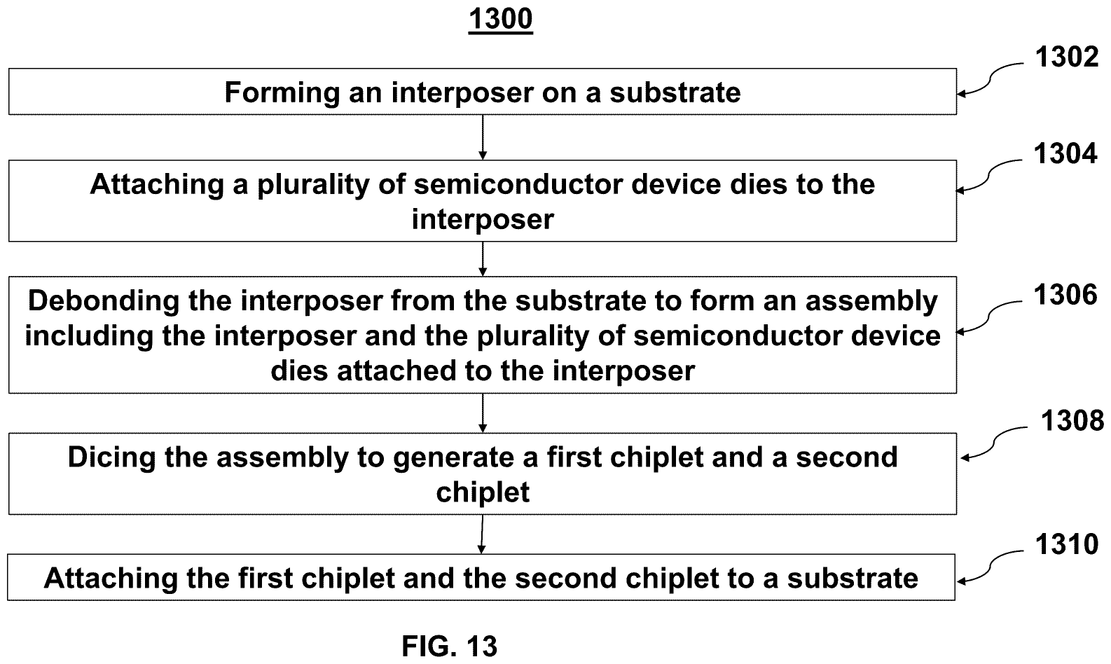

FIG. 13 is a flowchart illustrating various operations of a method 1300 of fabricating a semiconductor device, according to various embodiments. In operation 1302, the method 1300 may include forming an interposer 108 on a substrate 202 (e.g., see FIGS. 2 and 6). In operation 1304, the method 1300 may further include attaching a plurality of semiconductor device dies (e.g., semiconductor device dies 104 in FIG. 3 or first semiconductor device dies 104a and second semiconductor device dies 104b in FIG. 7) to the interposer 108. In operation 1306, the method 1300 may include debonding the interposer 108 from the substrate 202 (e.g., see FIGS. 5 and 9) to form an assembly including the interposer 108 and the plurality of semiconductor device dies (e.g., 104, 104a, and 104b of FIGS. 5 and 9) attached to the interposer 108.

In operation 1308, the method 1300 may include dicing the assembly to generate a first chiplet 506 (e.g., see FIG. 5) and a second chiplet 906 (e.g., see FIG. 9). In operation 1310, the method 1300 may further include attaching the first chiplet 506 and the second chiplet 906 to a package substrate 110 (e.g., see FIGS. 10 to 12). In various embodiments, the method 1300 may further include forming the first chiplet 506 to include a serializer/de-serializer device die 106 (e.g., see FIGS. 1A to 1C) and a portion of the diced interposer 108 (e.g., see FIG. 5). The method 1300 may further including attaching the first chiplet 506 such that the serializer/de-serializer device die 106 is located proximate to a sidewall 128 of the package substrate 110 (e.g., see FIGS. 1G and 10 to 12).

The method 1300 may further include forming the second chiplet 906 to include a SoC die 104b and an HBM die 104c attached to a second portion of the diced interposer 108b. The method 1300 may further include attaching the second chiplet 906 to the package substrate 110 (e.g., see FIGS. 1G and 10 to 12) such that electrical connections are formed between the serializer/de-serializer die 104a, the SoC die 104b, and the HBM die 104c. The method 1300 may further include forming the second chiplet 906 to include a deep trench capacitor 1202 within the second portion of the diced interposer 108b such that the deep trench capacitor 1202 has electrical connections to the SoC die 104b and to the HBM die 104c.

Referring to all drawings and according to various embodiments of the present disclosure, a semiconductor device is provided. The semiconductor device may include a package substrate 110; a first interposer 108a disposed on and coupled to the package substrate 110; a first semiconductor device die 104a disposed on and coupled to the first interposer 108a; a second interposer 108b disposed on and coupled to the package substrate 110; a second semiconductor device die 104b disposed on and coupled to the second interposer 108b (e.g., see FIGS. 10 to 12). The first semiconductor device die 104a may be a serializer/de-serializer die and the first semiconductor device die 104a is located proximate to a sidewall of the substrate 110. In a further embodiment, the second interposer 108b may be further coupled to a third semiconductor device die 104c. According to an embodiment, the first semiconductor device die 104a may be a serializer/de-serializer device die 106 (e.g., see FIGS. 1A to 1C) and the first semiconductor device die 140a coupled to the first interposer 108a may be located proximate to a sidewall 128 of the package substrate 110 (e.g., see FIGS. 1G and 10 to 12).

In one embodiment, the second semiconductor device die 104b may be an SoC die. In one embodiment, the second interposer 108b may also be coupled to an HBM die 104c. In one embodiment, the first interposer 108a may be an organic interposer and the second interposer 108b may be a silicon interposer. In one embodiment, the second interposer 108 may also include a deep trench capacitor 1202. In one embodiment, the first interposer 108a and the second interposer 108b may each be organic interposers. In one embodiment, a smallest distance between the first interposer 108a and the second interposer 108b may be greater than or equal to approximately 2 mm. In one embodiment, at least one of the first interposer 108a and the second interposer 108b may be a hybrid organic/silicon interposer.

In a further embodiment, there may be a difference in height 130 between a top surface of the first interposer 108a and a top surface of the second interposer 108b (e.g., see FIGS. 10 to 12), or there may be a difference in height 132 between a top surface of the first semiconductor device die 104a and a top surface of the second semiconductor device die 104b and the third semiconductor device die 104c (e.g., see FIG. 11). In a further embodiment, the second interposer 108b may include through-substrate via structures 1104 that are configured to provide vertical signal paths. The second interposer 108b may further include horizontal interconnection paths, which include metal interconnect structures 1106 embedded in dielectric material layers 1108, which are configured to provide high bandwidth chip-to-chip signal paths.

The above-described embodiments provide a number of advantages over conventional systems. For example, placing various semiconductor device dies on separate, smaller, interposers allows greater flexibility with regard to placement of various semiconductor device dies relative to an underlying package substrate. In this regard, placing a serializer/de-serializer device die 106 (e.g., see FIGS. 1A to 1C) proximate to a sidewall 128 of a package substrate 110 (e.g., see FIGS. 1G and 10 to 12) may allow a length of electrical pathways 118 to be reduced. In turn, reduced lengths of electrical pathways 118 may exhibit a reduced impedance resulting in lower ohmic loss and reduced RC delays. The use of smaller interposers also reduces complexity of fabrication of interposers and similarly may lower impedance associated with redistribution interconnect structures associated with the interposers.

The methods of fabricating chiplets (e.g., first chiplets 506 and second chiplets 906 of FIGS. 10 to 12) described above with reference to FIGS. 2 to 9 allow mass production of chiplets having one or more semiconductor device dies attached to interposers. Such chiplets (e.g., first chiplets 506 and second chiplets 906 of FIGS. 10 to 12) may be combined in various ways to fabricate three-dimensional devices having improved integration density and other advantages, such as faster speeds and higher bandwidth, due to decreased lengths of interconnects between semiconductor device dies residing on separate, smaller, interposers.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A semiconductor device, comprising:
a substrate;
a first interposer disposed on and coupled to the substrate;
a first semiconductor device die disposed on and coupled to the first interposer;
a second interposer disposed on and coupled to the substrate; and
a second semiconductor device die disposed on and coupled to the second interposer,
wherein the first semiconductor device die is a serializer/de-serializer die and the first semiconductor device die is located proximate to a sidewall of the substrate.

2. The semiconductor device of claim 1, wherein the second semiconductor device die is a system on chip (SoC) die.

3. The semiconductor device of claim 2, wherein the second interposer is also coupled to a high bandwidth memory (HBM) die.

4. The semiconductor device of claim 1, wherein the first interposer is an organic interposer and the second interposer is silicon interposer.

5. The semiconductor device of claim 4, wherein the second interposer further comprises a deep trench capacitor.

6. The semiconductor device of claim 1, wherein the first interposer and the second interposer are each organic interposers.

7. The semiconductor device of claim 1, wherein a smallest distance between the first interposer and the second interposer is greater than or equal to approximately 2 mm.

8. The semiconductor device of claim 1, wherein at least one of the first and second interposers is a hybrid organic/silicon interposer.

9. A semiconductor device, comprising:
a substrate;
a first interposer disposed on and coupled to the substrate;
a first semiconductor device die disposed on and coupled to the first interposer;
a second interposer disposed on and coupled to the substrate; and
a second semiconductor device die and to a third semiconductor device die each disposed on and coupled to the second interposer.

10. The semiconductor device of claim 9, wherein the first semiconductor device die is a serializer/de-serializer die and the first semiconductor device die is located proximate to a sidewall of the substrate.

11. The semiconductor device of claim 9, wherein the second semiconductor device die is a system on chip (SoC) die.

12. The semiconductor device of claim 11, wherein the third semiconductor device die is an HBM die.

13. The semiconductor device of claim 9, wherein there is a difference in height between a top surface of the first interposer and a top surface of the second interposer.

14. The semiconductor device of claim 9, wherein there is a difference in height between a top surface of the first semiconductor device die and a top surface of the second semiconductor device die and the third semiconductor device die.

15. The semiconductor device of claim 9, wherein the first interposer is an organic interposer and the second interposer is a silicon interposer.

16. The semiconductor device of claim 15, wherein the second interposer further comprises:
through-substrate via structures that are configured to provide vertical signal paths; and
horizontal interconnection paths, which include metal interconnect structures embedded in dielectric material layers, which are configured to provide high bandwidth chip-to-chip signal paths.

17. A semiconductor device, comprising:
a substrate;
a first interposer disposed on and coupled to the substrate;
a first semiconductor device die disposed on and coupled to the first interposer;
a second interposer disposed on and coupled to the substrate;
a second semiconductor device die disposed on and coupled to the second interposer;
a third interposer disposed on and coupled to the substrate; and
a third semiconductor device die disposed on and coupled to the third interposer,
wherein the first interposer, the second interposer, and the third interposer are separated from each other on the substrate, and wherein the first interposer and the third interposer are located proximate to a sidewall of the substrate.

18. The semiconductor device of claim 17, wherein the first semiconductor device die and the third semiconductor device die are each serializer/de-serializer dies.

19. The semiconductor device of claim 17, wherein the second semiconductor device die is a system on chip (SoC) die.

20. The semiconductor device of claim 17, wherein the second further comprises:
through-substrate via structures that are configured to provide vertical signal paths; and
horizontal interconnection paths, which include metal interconnect structures embedded in dielectric material layers, which are configured to provide high bandwidth chip-to-chip signal paths.
